(19) United States
(12) Patent Application Publication
(10) Pub. No.: US 2025/0247995 A1
(43) Pub. Date: Jul. 31, 2025

(54) ELECTRONIC DEVICE

(71) Applicant: Lenovo (Beijing) Limited, Beijing (CN)

(72) Inventor: Lu CHENG, Beijing (CN)

(21) Appl. No.: 19/031,002

(22) Filed: Jan. 17, 2025

(30) Foreign Application Priority Data
Jan. 31, 2024 (CN) 202410139336.X

(51) Int. Cl. H05K 7/20; G06F 1/20

(52) U.S. Cl. CPC H05K 7/20145; G06F 1/203; H05K 7/20154; H05K 7/20172; H05K 7/20209; G06F 2200/201

(57) ABSTRACT

An electronic device includes a body, a first heating element, a second heating element, and a heat dissipation member. The body includes a first side and a second side arranged opposite to the first side. The first heating element is arranged inside the body close to the first side. The second heating element is arranged inside the body close to the second side. The heat dissipation member is arranged between the first heating element and the second heating element and configured to dissipate heat for the first heating element and/or the second heating element.

### CROSS-REFERENCE TO RELATED APPLICATION

The present disclosure claims priority to Chinese Patent Application No. 202410139336.X, filed on Jan. 31, 2024, the entire content of which is incorporated herein by reference.

### TECHNICAL FIELD

The present disclosure is related to the electronic device technology field and, more particularly, to an electronic device.

### BACKGROUND

An electronic device often includes a plurality of heating elements arranged next to each other, e.g., CPU and GPU arranged at the same motherboard. The heat of the plurality of heating elements is dissipated through a heat dissipation assembly. Since the heat generated by the plurality of heating elements is concentrated, the heat dissipation effect is affected.

### SUMMARY

An aspect of the present disclosure provides an electronic device, including a body, a first heating element, a second heating element, and a heat dissipation member. The body includes a first side and a second side arranged opposite to the first side. The first heating element is arranged inside the body close to the first side. The second heating element is arranged inside the body close to the second side. The heat dissipation member is arranged between the first heating element and the second heating element and configured to dissipate heat for the first heating element and/or the second heating element.

### BRIEF DESCRIPTION OF THE DRAWINGS

FIG. 1 illustrates a schematic structural diagram of an electronic device according to some embodiments of the present disclosure.

FIG. 2 illustrates a schematic structural diagram of an electronic device in a first heat dissipation status according to some embodiments of the present disclosure.

FIG. 3 illustrates a schematic structural diagram of an electronic device in a second heat dissipation status according to some embodiments of the present disclosure.

FIG. 4 illustrates a schematic structural diagram of an electronic device in a third heat dissipation status according to some embodiments of the present disclosure.

FIG. 5 illustrates a schematic structural diagram of an electronic device in a vent-closed status according to some embodiments of the present disclosure.

FIG. 6 illustrates a schematic structural diagram of an electronic device in a vent opened status according to some embodiments of the present disclosure.

FIG. 7 illustrates a schematic structural diagram of another electronic device according to some embodiments of the present disclosure.

### DETAILED DESCRIPTION OF THE EMBODIMENTS

The present disclosure provides an electronic device to improve heat dissipation performance.

The technical solutions of embodiments of the present disclosure are described in detail below in conjunction with the accompanying drawings of embodiments of the present disclosure. Obviously, the described embodiments are only some embodiments of the present disclosure, not all embodiments. Based on embodiments of the present disclosure, all other embodiments obtained by those skilled in the art without creative efforts shall fall within the scope of the present disclosure.

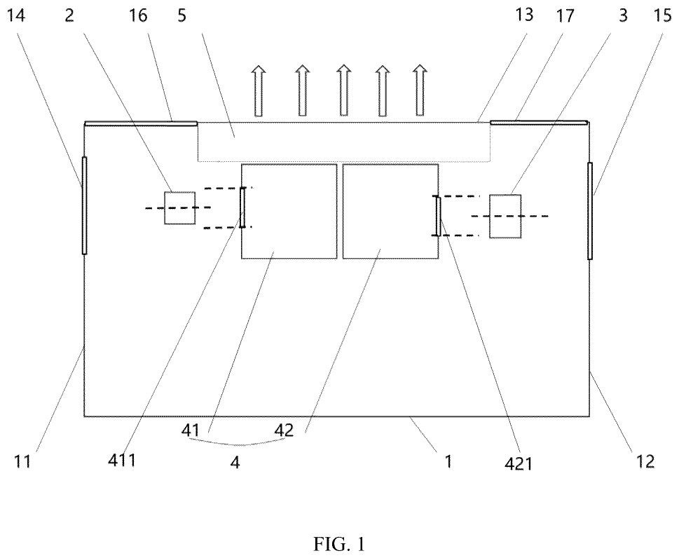

FIG. 1 illustrates a schematic structural diagram of an electronic device according to some embodiments of the present disclosure. The electronic device includes a body 1, a first heating element 2, a second heating element 3, and a heat dissipation member 4. The body 1 includes a first side 11 and a second side facing the first side 11. The first heating element 2 and the second heating element are arranged inside the body 1. The first heating element 2 is close to the first side 11. The second heating element 3 is close to the second side 12. The heat dissipation member 4 is arranged between the first heating element 2 and the second heating element 3 and configured to dissipate heat of the first heating element 2 and/or the second heating element 3.

In the electronic device of embodiments of the present disclosure, the heat dissipation member 4 can be arranged between the first heating element 2 and the second heating element 3. Thus, the first heating element 2 and the second heating element 3 can be arranged at an interval relative to the heat dissipation member 4, which effectively avoids the heat dissipation member 4 to dissipate the heat of the first heating element 2 and the second heating element 3 together to cause the heat generated by the first heating element 2 and the second heating element 3 to be concentrated. Then, the heat dissipation member 4 can perform heat dissipation on the first heating element 2 and/or the second heating element 3 to cause the first heating element 2 and the second heating element 3 to have a distributive heat dissipation aided by the heat dissipation member 4. Thus, the heat dissipation performance can be effectively improved. In embodiments of the present disclosure, the first heating element 2 and the second heating element 3 can be two independent heating elements. According to the application status of the electronic device, the heat generated by the first heating element 2 and the second heating element 3 can be different.

For example, the first heating element 2 can include a Central Processing Unit (CPU), and the second heating element 3 can include a Graphics Processing Unit (GPU).

The CPU can focus more on scheduling, coordination, and management with certain computational capabilities. The GPU can primarily focus on image processing and large matrix operations, such as machine learning algorithms. The tasks processed by the CPU and the GPU can be different. Thus, when the electronic device performs different tasks, the heat amounts generated by the CPU and the GPU can be different.

That is, when only the CPU or GPU is loaded, the temperature difference between the first heating element 2 and the second heating element 3 can be significant. Heat dissipation can be performed on the first heating element 2 and the second heating element separately according to the above configuration.

In some embodiments, the electronic device can include a laptop. The first heating element 2 can be the CPU, and the second heating element 3 can be the GPU. An input assembly (e.g., keyboard) can be arranged on a first surface (a plane in a direction faced by FIG. 1) of the body 1, and the screen of the laptop can be hinged with a third side (a top side of the body 1 in FIG. 1 intersecting with the first side 11 and the second side 12) of the body 1.

Under the same noise and power consumption conditions, when the CPU and GPU (the first heating element 2 and the second heating element 3) are heavily loaded, the temperature of the screen can be lowered by 3.27° C., and the temperature of the first surface can be lowered by 6.86° C.

Under the same noise and power consumption conditions, when only the CPU is heavily loaded, the average temperature of the CPU can be lowered by 4.2° C.

The heat dissipation member 4 is arranged between the first heating element 2 and the second heating element 3 and configured to dissipate heat of the first heating element 2 and/or the third heating element 3. Thus, according to the operation status of the electronic device, the heat dissipation statuses of the heat dissipation member 4 to the first heating element 2 and the second heating element 3 can be controlled. For example, when the heat amount generated by the first heating element 2 is relatively high, the heat dissipation member 4 can be controlled to dissipate heat from the first heat dissipation member 2, and the heat dissipation member 4 may not dissipate heat for the second heat element 3. In some other embodiments, the heat dissipation member 4 can be mainly controlled to dissipate heat for the first heating element 2. Thus, at the moment, the heat dissipation performance of the heat dissipation member 4 to the first heating element 2 can be better than the heat dissipation performance of the heat dissipation member 4 to the second heating element 3.

In some embodiments, the heat dissipation member 4 can be also arranged inside the body 1 to facilitate the layout of the electronic device. Of course, the heat dissipation member 4 can also be arranged outside the body 1 to dissipate heat for the first heating element 2 and the second heating element 3 separately. In some embodiments, the heat dissipation member 4 can be a member capable of driving airflow, such as a fan. A first vent 14 can be arranged at the first side 11. The first heating element 2 can be arranged between the first vent 14 and the heat dissipation member 4. A second vent 15 can be arranged at the second side 12. The second heating element 3 can be arranged between the second vent 15 and the heat dissipation member 4.

Through the above configuration, when the heat dissipation member 4 dissipates heat for the first heating element 2, the heat dissipation member 4 can be configured to generate airflow. The airflow can circulate among the heat dissipation member 4, the first heating element 2, and the first vent 14. Since the first heating element 2 is close to the first side 11, and the first vent 14 is arranged at the first side 11, an airflow path of the airflow can be shortened to quickly transfer the heat generated by the first heating element 2 to the outside of the body to improve the heat dissipation performance.

Similarly, when the heat dissipation member 4 performs the heat dissipation on the second heating element 3, the airflow can circulate among the heat dissipation member 4, the second heating element 3, and the second vent 15. Since the second heating element 3 is close to the second side 12, and the second vent 15 is arranged at the second side 12, the airflow path of the airflow can be shortened to quickly transfer the heat generated by the second heating element 3 to the outside of the body 1 to improve the heat dissipation performance.

As shown in FIG. 1, the first side 11 of the body 1 is the left side of the body 1 in FIG. 1. The second side 12 of the body 1 is the right side of the body 1 in FIG. 1. In embodiments of the present disclosure, the electronic device can be the laptop. When the screen of the laptop and the body 1 are unfolded, and the screen faces the user, the first side 11 of the body 1 can be on the left side of the user, and the second side 12 of the body 1 can be on the right side of the user. Based on the above configuration, the air carrying the heat can flow out of the body 1 from two sides of the body 1 to avoid the airflow toward the user. Thus, the user application comfort can be improved.

Moreover, since the first side 11 and the second side 12 are arranged opposite to each other, the first heat dissipation path of the heat dissipation member 4 for the first heating element 2 (along the layout direction of the heat dissipation member 4, the first heating element 2, and the first vent 14) and the second heat dissipation path of the heat dissipation member 4 for the second heating element 3 (along the layout direction of the heat dissipation member 4, the second heating element 3, and the second vent 15) can be relatively independent and do not interfere with each other. By ensuring the heat dissipation performance, the heat generated by the first heating element 2 and the second heating element 3 can be prevented from being concentrated. Thus, the excessive local temperature can be avoided in the electronic device.

In some embodiments, the heat dissipation member can be a member capable of driving the airflow, such as a fan. The body 1 can include a third side. The third side can intersect the first side 11 and the second side 12. A third vent can be arranged on the third side. The heating dissipation member 4 can correspond to the third vent 13.

The third vent 13 can be the primary vent. Other vents can also be arranged on the third side, such as a first auxiliary vent 16 and a second auxiliary vent 17. The first auxiliary vent 16 can be arranged on a side of the third vent 13 close to the first side 11. The second auxiliary vent 17 can be arranged on one side of the third vent 13 close to the second side 12.

A heat conduction member 6 can be provided. The heat conduction member 6 can include a first heat conduction part and a second heat conduction part. The first heat conduction part can be connected to the first heating element 2 and/or the second heating element 3 to transfer heat. The second heat conduction part can be arranged at the third vent 13. The third vent 13 can correspond to the vent of the heat dissipation member 4 to cause the airflow flowing out from the vent of the heat dissipation member 4 to dissipate the heat of the second heat conduction part. According to the above configuration, the heat of the first heating element 2 and/or the second heating element 3 can be transferred to the second heat conduction part of the heat conduction member 6 through the first heat conduction part of the heat conduction member 6, and then, the heat dissipation member 4 can perform heat dissipation on the second heat conduction part. Then, the heat of the first heating element 2 and/or the second heating element 3 can be dissipated.

In some embodiments, the first heat conduction part of the heat conduction member 6 can be only connected to the first heating element 2. That is, the heat of the first heating element 2 can be transferred to the second heat conduction part of the heat conduction member 6 through the first heat conduction part of the heat conduction member 6. Then, the heat dissipation member 4 can perform the heat dissipation on the second heat conduction part to dissipate the heat of the first heating element. The heat dissipation member 4 can directly perform the heat dissipation on the first heating element 2. That is, the heat dissipation member 4 can drive a part of the airflow to flow to the first heating element 2. Another part of the airflow driven by the heat dissipation member 4 can flow to the third vent 13. In embodiments of the present disclosure, the heat dissipation member 4 can directly perform the heat dissipation on the second heating element 3.

Similarly, the first heat conduction part of the heat conduction member 6 can be only connected to the second heating element 3. That is, the heat from the second heating element 3 can be transferred to the second heat conduction part of the heat conduction member 6 through the first conduction part of the heat conduction member 6. Then, the heat dissipation member 4 can perform the heat dissipation on the second heat conduction part to dissipate the heat of the second heating element 3. The heat dissipation member 4 can directly perform the heat dissipation on the second heating element 3. That is, the heat dissipation member 4 can drive a part of the airflow to flow to the second heating element 3. The heat dissipation member 4 can drive another part of the airflow to flow to the third vent 13 through the second heat conduction part. In some embodiments, the heat dissipation member 4 can directly perform the heat dissipation on the first heating element 2.

Furthermore, the first heat conduction part of the heat conduction member 6 can be connected to the first heating element 2 and the second heating element 3. In some embodiments, the at least two heat conduction members 6 can be provided. The first heat conduction parts of a part of the heat conduction members 6 can be connected to the first heating element 2. The first heat connection parts of another part of the heat conduction members 6 can be connected to the second heating element 3. The second heat conduction parts of all the heat conduction members 6 can be arranged at the third vent 13. The heat dissipation member 4 can drive the airflow to only flow through the second heat conduction part and flow out of the body 1 from the third vent 13. That is, the heat dissipation member 4 can indirectly dissipate heat for the first heating element 2 and the second heating element through the heat conduction member 6. The heat dissipation member 4 can also drive a part of the airflow to flow to the heating element (the first heating element 2 and the second heating element 3). The heat dissipation member 4 can drive another part of the airflow to flow to the third vent 13 through the second conduction part.

The heat conduction member 6 can include a heat transfer assembly, which is configured to transfer the heat. The heat transfer assembly can include a heating pipeline, a heat uniform plate, or a combination thereof. Of course, the heat conduction member 6 can have other structures, as long as the structure can realize heat transfer. That is, as a member in the heat dissipation path of the heating element (the first heating element 2 and/or the second heating element 3), the heat conduction member 6 can guide the heat transfer direction to be transferred with the pure airflow carrying the heat to facilitate the arrangement of the position (e.g., the third vent 13) where the heat flows out of the body 1.

Of course, to improve the heat dissipation performance, the electronic device can also include a heat dissipation fin 5. The heat dissipation fin 5 can be connected to the heat conduction member 6. The heat dissipation fin 5 can be arranged to correspond to the third vent 13. The first side 11 and the second side 12 can be arranged in the first direction. The length of the heat dissipation fin 5 along the first direction can be not smaller than the length of the third vent 13 to ensure that the airflow can flow out from the third vent 13 via the heat dissipation fin 5. Moreover, the length of the heat dissipation fin 5 can be not greater than the length of the heat conduction member 6. Thus, the heat transferred by the heat conduction member 6 can be effectively distributed at the heat dissipation fin 5 along the length of the heat dissipation fin 5 to further improve the heat dissipation performance.

Of course, the heat dissipation member 4 can also drive the airflow to pass through the first heating element 2 and/or the third heating element 3 to flow out from the third vent 13 to dissipate the heat. In the flow path of the airflow, other heating elements can be provided to perform the heat dissipation on the other heating elements and avoid the arrangement (e.g., arrangement for additional heat dissipation members) for the other heating elements.

In some other embodiments, the heat conduction member 6 can be directly provided. The heat conduction member 6 can include a first heat conduction part and a second heat conduction part. The first heat conduction part can be connected to the first heating element 2 and/or the second heating element 3 to transfer heat. The second heat conduction part can correspond to the vent of the heat dissipation member 4. The airflow flowing out from the vent of the heat dissipation member 4 can dissipate the heat of the second heat conduction part. The second heat conduction part can be arranged inside the first body away from the position of the heating element (the first heating element 2 and/or the second heating element. Alternatively, the second heat conduction member can correspond to the first vent 14 and/or the second vent 15. The second heat conduction part can pass through the wall surface of the body 1 to be arranged outside of the body 1.

In some embodiments, as shown in FIG. 1, the first vent 14 is arranged at the first side 11 of the body 1, and the second vent 15 can be arranged at the second side 12. The third vent 13, the first auxiliary vent 16, and the second auxiliary vent 17 can be arranged on the third side of the body 1. By controlling the first vent 14, the second vent 15, the first auxiliary vent 16, and the second auxiliary vent 17 can be controlled to open and close, the heat dissipation status can be adjusted for the first heating element 2 and the second heating element 3.

In some embodiments, the third vent 13 can be always open. The first vent 14, the second vent 15, the first auxiliary vent 16, and the second auxiliary vent 17 can be auxiliary vents. By controlling different auxiliary vents to open and close, the heat dissipation status of the first heating element 2 and the second heating element 3 can be adjusted.

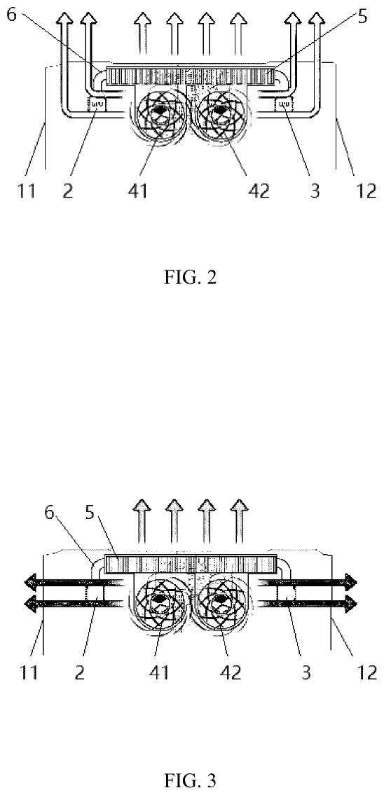

As shown in FIG. 1 and FIG. 2, in the first heat dissipation status, the first vent 14 and the second vent 15 are closed, while the first auxiliary vent 16 and the second auxiliary vent 17 are open. Alternatively, the body 1 only includes the third vent 13, the first auxiliary vent 16, and the second auxiliary vent 17, without the first vent 14 and the second vent 15. The heat dissipation member 4 includes a first heat dissipation member 41 and a second heat dissipation member 42. A part of the airflow driven by the first heat dissipation member 41 can pass through the heat conduction member 6 and the heat dissipation fin 5 to indirectly dissipate heat for the first heating element 2. The part of the airflow can pass through the third vent to flow out of the body 1. The first heat dissipation member 41 can drive another part of the airflow to directly pass through the first heating element 2 to dissipate heat. Another part of the airflow can pass through the first auxiliary vent 16 to flow out of the body 1. Similarly, the second heat dissipation member 42 can drive a part of the airflow to pass through the heat conduction member 6 and the heat dissipation fin 5 to indirectly perform the heat dissipation on the second heating element 3. The part of the airflow can pass through the third vent 13 to flow out of the body 1. The second heat dissipation member 42 can drive another part of the airflow to directly pass through the second heating element 3 to dissipate heat. Another part of the airflow can pass through the second auxiliary vent 17 to flow out of the body 1. In some embodiments, the airflow used by the heat dissipation member 4 to perform the heat dissipation on the first heating element 2 and the second heating element 3 can flow out of the body 1 through the third side.

As shown in FIG. 1 and FIG. 3, in the second heat dissipation status, the first vent 14 and the second vent 15 are open, while the first auxiliary vent 16 and the second auxiliary vent 17 are closed. Alternatively, the body can only include the third vent 13, the first vent 14, and the second vent 15, without the first auxiliary vent 16 and the second auxiliary vent 17. The third vent 13, the first vent 14, and the second vent 15 can be always open. The heat dissipation member 4 includes the first heat dissipation member 41 and the second heat dissipation member 42. The first heat dissipation member 41 can drive a part of the airflow to pass through the heat conduction member 6 and the heat dissipation fin 5 to indirectly perform the heat dissipation on the first heating element 2. The part of the airflow can pass through the third vent 13 to flow out of the body 1. The first heat dissipation member 41 can drive another part of airflow to directly pass through the first heating element 2 to dissipate heat. Another part of the airflow can flow out of the body 1 through the first vent 14. Similarly, the second heat dissipation member 42 can drive a part of the airflow to pass through the heat conduction member 6 and the heat dissipation fin 5 to indirectly perform the heat dissipation on the second heating element 3. The part of the airflow can pass through the third vent 13 to flow out of the body 1. The second heat dissipation member 42 can drive another part of the airflow to directly pass through the second heating element 3 to dissipate heat. Another part of the airflow can pass through the second vent 15 to flow out of the body 1. In some embodiments, the airflow used by the heat dissipation member 4 to perform the heat dissipation on the first heating element 2 and the second heating element 3 can flow out of the body through the first side 11, the second side 12, and the third side.

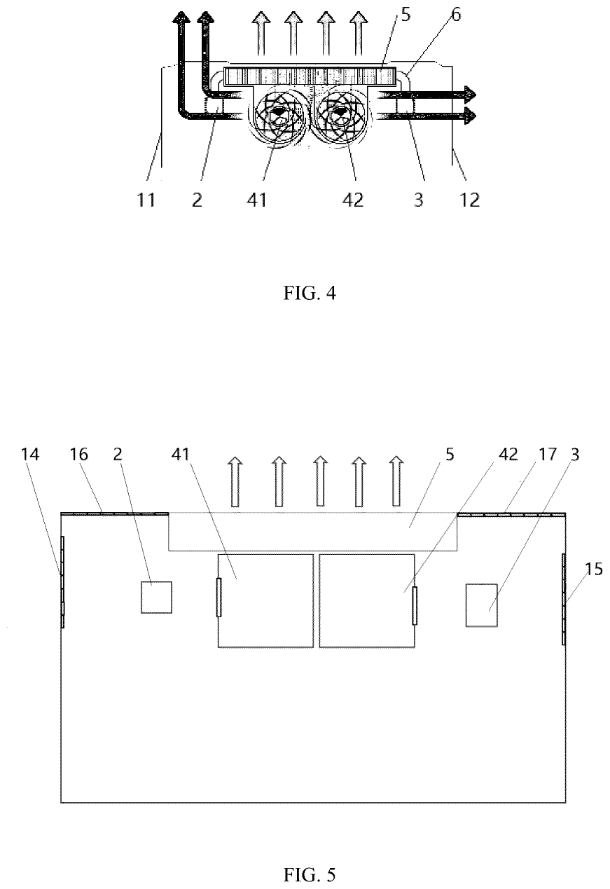

As shown in FIG. 1 and FIG. 4, in the third heat dissipation status, the first auxiliary vent 16 and the second vent 15 are open, while the first vent 14 and the second auxiliary vent 17 are closed. Alternatively, the body 1 can only include the third vent 13, the first auxiliary vent 16, and the second vent 15, without the first vent 14 and the second auxiliary vent 17. The third vent 13, the first auxiliary vent 16, and the second vent 15 can be always open. The heat dissipation member 4 includes the first heat dissipation member 41 and the second heat dissipation member 42. The first heat dissipation member 41 can drive a part of the airflow to pass through the heat conduction member 6 and the heat dissipation fin 5 to indirectly perform the heat dissipation on the first heating element 2. The part of the airflow can pass through the third vent 13 to flow out of the body 1. The first heat dissipation member 41 can drive another part of the airflow to directly pass through the first heating element 2 to dissipate heat. Another part of the airflow can pass through the first auxiliary vent 16 to flow out of the body 1. The second heat dissipation member 42 can drive another part of the airflow to pass through the heat conduction member 6 and the heat dissipation fin 5 to indirectly perform the heat dissipation on the second heating element 3. Another part of the airflow can pass through the third vent 13 to flow out of the body 1. The second heat dissipation member 42 can drive another part of the airflow to directly pass through the second heating element 3 to dissipate heat. Another part of the airflow can pass through the second vent 15 to flow out of the body 1. In some embodiments, the airflow used by the heat dissipation member 4 to perform the heat dissipation on the first heating element 2 and the second heating element 3 can flow out of the body through the second side 12 and the third side.

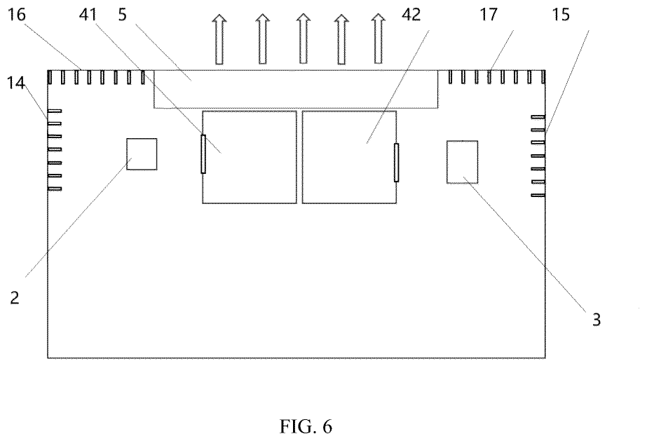

As shown in FIG. 1 and FIG. 6, in the fourth heat dissipation status, the first vent 14, the second vent 15, the first auxiliary vent 16, and the second auxiliary vent 17 are open. Alternatively, the body 1 includes the third vent 13, the first vent 14, the second vent 15, the first auxiliary vent 16, and the second auxiliary vent 17, which are always open. The heat dissipation member 4 includes the first heat dissipation member 41 and the second heat dissipation member 42. The first heat dissipation member 41 can drive a part of the airflow to pass through the heat conduction member 6 and the heat dissipation fin 5 to indirectly perform the heat dissipation on the first heating element 2. The part of the airflow can flow out of the body 1 through the third vent 13. Another part of the airflow driven by the first heat dissipation member 41 can directly pass through the first heating element 2 to dissipate heat. Another part of the airflow can flow out of the body 1 through the first vent 14 and the first auxiliary vent 16. The second heat dissipation member 42 can drive a part of the airflow to pass through the heat conduction member 6 and the heat dissipation fin 5 to indirectly perform the heat dissipation on the second heating element 3. The part of the airflow can flow out of the body 1 through the third vent 13. Another part of the airflow driven by the second heat dissipation member 42 can directly pass through the second heating element 3 to dissipate heat. Another part of the airflow can flow out of the body 1 through the second vent 15 and the second auxiliary vent 17. In some embodiments, the airflow used by the heat dissipation member 4 to perform the heat dissipation on the first heating element 2 and the second heating element 3 can flow out of the body 1 through the first side 11, the second side 12, and the third side.

According to the above configuration, the direction of the airflow flowing out of the body 1 can be adjusted as needed. The airflow can be used to perform the heat dissipation on the first heating element 2 and the second heating element 3. For example, when the temperature of the first heating element 2 and the second heating element 3 are relatively high, the electronic device can be maintained in the second heat dissipation status or the third heat dissipation status to prevent concentrated hot air from being blown out of the body 1, thereby avoiding excessive local temperature in the electronic device. The service life of the electronic device can be effectively extended.

Taking the laptop as an example, the body 1 can be a first section having a keyboard and a second section hinged to the first section can have a screen. When the hot air is concentratedly blown out from a hinged side (third side) of the first section and the second section, the temperature of the screen can easily rise to affect the touch and control of the user on the screen as well as the application of the screen. Thus, by controlling the electronic device to maintain the second heat dissipation status or the third heat dissipation status, the hot air can be blown out from different positions of the first section (the first side 11, the second side 12, and the third side), which avoids the concentration of the hot air.

To improve the flexibility for the heat dissipation, the outlet of the heat dissipation member 4 can include the first outlet 411 facing the first side 11 of the body 1, the second outlet 421 facing the second side 12 of the body 1, and/or the third outlet facing the third side of the body 1.

As shown in FIG. 1, in some embodiments, the centerline of the first heating element 2 (in the first direction) is arranged between the upper boundary and the lower boundary of the first outlet 411. That is, at least more than half of the area of the first heating element 2 can correspond to the first direction of the first outlet 411 to ensure that the airflow flowing out of the first outlet 411 is effectively used to perform the heat dissipation on the first heating element 2. In some embodiments, the projection of the first heating element 2 in the first direction can be within the projection of the first outlet 411 in the first direction.

Similarly, the centerline of the second heating element 3 (in the first direction) can be arranged between the upper boundary and the lower boundary of the second outlet 421. That is, at least more than half of the area of the second heating element 3 can correspond to the second outlet 421 in the first direction to ensure that the airflow flowing out of the second outlet 421 is effectively used to perform the heat dissipation on the second heating element 3. In some embodiments, the projection of the second heating element 3 in the first direction can be within the projection of the second outlet 421 in the first direction.

In some embodiments, the outlet of the heat dissipation member 4 can include the first outlet, the second outlet, and the third outlet. The first outlet, the second outlet, and the third outlet outlets can be opened or closed. Different airflow directions of the heat dissipation member can be realized according to corresponding controls.

The heat dissipation member 4 can also include only one or two outlets.

For example, the heat dissipation member 4 can include the first heat dissipation member 41 and the second heat dissipation member 42, which can generate airflow. The first heat dissipation member 41 and the second heat dissipation member 42 each can have a third outlet. Moreover, the first heat dissipation member 41 can include the first outlet, and the second heat dissipation member 42 can include the second outlet. The first heat dissipation member 41 can simultaneously direct airflow through the first outlet and the third outlet, or the airflow can be unidirectional by controlling the first outlet and the third outlet to open and close. Similar to the above, the second heat dissipation member 42 can also simultaneously direct airflow through the second outlet and the third outlet, or the airflow can be unidirectional by controlling the second outlet and the third outlet to open and close.

In some embodiments, each of the first heat dissipation member 41 and the second heat dissipation member 42 can include a turbine assembly. The turbine assembly can rotate to generate airflow. That is, the first heat dissipation member 41 can include a first turbine assembly, and the second heat dissipation member 42 can include a second turbine assembly. The first turbine assembly and the second turbine assembly can have opposite rotation directions. Through the above configuration, the airflow directions can be opposite to generate airflows toward different directions.

In embodiments of the present disclosure, the heat dissipation member 4 can include a motor assembly to cause the turbine assembly to rotate. Two motor assemblies can be provided and correspond to the first heat dissipation member 41 and the second heat dissipation member 42, respectively. In some other embodiments, only one motor assembly can be provided to drive the first heat dissipation member 41 and the second heat dissipation member 42 to operate through a transmission assembly.

The heat dissipation member 4 can also include a plate body and a wall body. The plate body can surround the outer side of the turbine assemblies to block the airflow. The outlet can be formed between the wall body and the body 1 for the airflow to circulate. The outlet can include the first outlet, the second outlet, and the third outlet.

An orthogonal projection of the heat dissipation member 4 along the first direction can cover the orthogonal projection of the first heating element 2 and the second heating element 3 in the first direction. The first direction can be the layout direction of the first side 11 and the second side 12. According to the above configuration, the first heating element 2, the heat dissipation member 4, and the second heating element 3 can be arranged along a straight line. With the above configuration, the heat dissipation member 4, the first heating element 2, and the second heating element 3 can be arranged, and the airflow paths from the heat dissipation member 4 to the first heating element 2 and from the heat dissipation member 4 to the second heating element 3 can be effectively shortened to ensure the heat dissipation performance.

Furthermore, since the orthogonal projection of the heat dissipation member 4 in the first direction covers the orthogonal projection of the first heating element 2 in the first direction, and the orthogonal projection of the heat dissipation member 4 in the first direction covers the orthogonal projection of the second heating element 3 in the first direction, the heat dissipation member 4 can isolate the heat generated by the second heating element 3 from being transferred to the first heating element 2. Thus, the heat generated by the first heating element 2 and the heat generated by the second heating element 3 can be distributed to avoid the heat concentration and facilitate the heat dissipation operation.

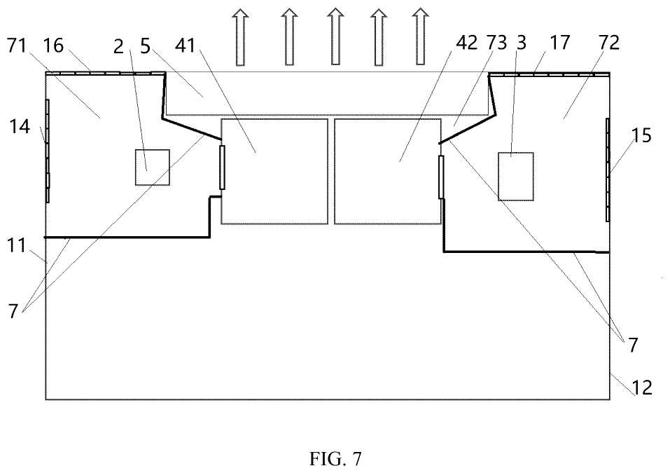

As shown in FIG. 7, the heat dissipation member 4 and the first side 11 form a first airflow guidance area 71 through an airflow guidance member 7. The first heating element 2 is arranged inside the first airflow guidance area 71. The heat dissipation member 4 and the second side 12 form a second airflow guidance area 72 through the airflow guidance member 7. The second heating element 3 can be arranged inside the second airflow guidance area 72. The airflow guidance areas can be formed by the airflow guidance member 7 to guide the airflow generated by the heat dissipation member 4 to pass through the heating elements (the first heating element 2 and the second heating element 3) to dissipate heat.

In some embodiments, the heat conduction member 6 and the airflow guidance member 7 can be provided. Since a side of the airflow guidance member 7 forming the first airflow guidance area 71 and a side of the airflow guidance member 7 forming the second airflow guidance area that are close to each other form a third airflow guidance area 73, the heat dissipation member 6 can at least be arranged partially inside the third airflow guidance area 73. In some embodiments, the heat dissipation fin 5 connected to the heat conduction member 6 can be also inside the third airflow guidance area 73.

In some embodiments, the airflow guidance member 7 can have a structure, such as a sponge strip, which is arranged at the motherboard having the heating element through bonding. Then, the airflow guidance member 7 can enclose the airflow guidance area with the physical structure of the heat dissipation member 4 (the wall body of the heat dissipation member 4) and the structure of the body 1. Moreover, the airflow guidance member 7 can provide support between the motherboard and the inner wall of the body 1, and stably support the motherboard.

The body 1 can include a vent. A control assembly can be arranged at each of the vents of the first airflow guidance area 71 and the second airflow guidance area 72. The control assembly can be configured to control the vent to be in the first status or the second status. An airflow amount of the vent in the first status can be different from an airflow amount of the vent in the second status.

The vent can be switched between allowing airflow or not allowing airflow. as shown in FIG. 1, FIG. 5, and FIG. 6, the third vent 13 (corresponding to the heat dissipation fin 5), the first auxiliary vent, 16, and the second auxiliary vent 17 are provided at the third side of the body 1. The first vent 14 is arranged at the first side 11 of the body 1. The second vent 15 is arranged at the second side 12 of the body 1. The third vent 13 can be the primary vent. The auxiliary vents (the first vent 14, the second vent 15, the first auxiliary vent 16, and the second auxiliary vent 17) can each include a control assembly, which is controlled to control the vent to open and close and the airflow amount. The control assemblies of the four auxiliary vents can be independent of each other. That is, the control assembly can control the corresponding auxiliary vent to open and close and the airflow amount. The control assemblies of the four auxiliary vents can be associated with each other to realize the corresponding venting solution.

The control assembly can be made of a memory alloy. The memory alloy can have a plastic shape change within a temperature range and restore to the original macro shape. The heat of the heating element can be transferred to the control assembly through the air or indirectly in connection with the heat conduction member. Thus, the control assembly can be configured to control the vent to open and close and adjust the airflow amount.

In some embodiments, when the temperature of the control assembly is higher than a determined value T1 and smaller than a determined value T2, the memory alloy can contract to change shape to allow some auxiliary vents (e.g., the first auxiliary vent 16 and the second auxiliary vent 17) to open automatically. When the temperature of the control assembly is higher than the determined value T2, some other auxiliary vents (e.g., the first vent 14 and the second vent 15) can automatically open. When the electronic device is in a low power consumption scenario, the temperature of the control assembly can be smaller than T1, the memory alloy can be restored to the original status, and the auxiliary vents can be closed.

The control assembly can include a blade structure and a drive apparatus configured to control the blade to rotate (e.g., a micromotor). The four auxiliary vents (the first vent 14, the second vent 15, the first auxiliary vent 16, and the second auxiliary vent 17) each can be provided with a control assembly. A manual switch can be provided. In connection with the temperature detection apparatus (e.g., a plate end sensor) of the electronic device or a sensor additionally provided, the temperature of the body 1 (e.g., the environment temperature in the body 1 or the temperature of the heating element) can be detected. According to the detected temperature, when the detected temperature is greater than the determined value T1 and smaller than T2, the user can be prompted that some auxiliary vents can be selected to open. When the detected temperature is greater than the determined value T2, the user can be prompted that some other auxiliary vents can be opened. Automatic control can be set. In connection with the above sensor, when the detected temperature is greater than the determined value T1 and smaller than T2, the user can be prompted to select some auxiliary vents to open. When the detected temperature is greater than the determined value T2, the user can be prompted to open some other auxiliary vents. Thus, the auxiliary vents can be configured to guide the airflow and increase the heat exchange area.

As shown in FIG. 7, the primary vent is provided at the third side of the main body 1. The first vent 14 is arranged on the first side of the first airflow guidance area 71, and the first auxiliary vent 16 is arranged on the third side of the first airflow guidance area 71. The second vent 15 is arranged on the second side of the second airflow guidance area 72, and the second auxiliary vent 17 is arranged on the third side of the second airflow guidance area 72.

The first side of the first airflow guidance area 71 can correspond to the first side 11 of the body 1. For example, as shown in FIG. 7, the first side 11 of the body 1 is the left side of the body in the figure. The first side of the first airflow guidance area 71 is the left side of the first airflow guidance area 71. Similarly, the second side of the second airflow guidance area 72 corresponds to the second side 12 of the body 1. As shown in FIG. 7, the second side 12 of the body 1 is the right side of the body 1 in the figure. The second side of the second airflow guidance area 72 is the right side of the second airflow guidance area 72. The third side of the first airflow guidance area 71 corresponds to the third side of the body 1. As shown in FIG. 7, the third side of the body 1 is the top side of the body 1 in the figure. The third side of the first airflow guidance area 71 is the top side of the first airflow guidance area 71. Similarly, the third side of the second airflow guidance area 72 corresponds to the third side of the main body 1. As shown in FIG. 7, the third side of the main body 1 is the top side of the body 1 in the figure. The third side of the second airflow guidance area 72 is the top side of the second airflow guidance area 72.

The first vent 14 and the second vent 15 can be arranged opposite each other. The first auxiliary vent 16 and the second auxiliary vent 17 can be arranged on the same side as the primary vent.

In some embodiments, the auxiliary cent can be individually controlled to open and close.

Further, the electronic device of the present disclosure can also include an input assembly. The input assembly can be arranged on the first surface of the body 1. The orthogonal projection of the input assembly in the second direction can cover the first heating element 2, the second heating element 3, and the heat dissipation member 4. As shown in FIG. 1, the second direction is a direction perpendicular to the surface shown in the figure. The input assembly can cover the first heating element 2, the second heating element 3, and the heat dissipation member 4 to avoid exposing the first heating element 2, the second heating element 3, and the heat dissipation member 4. The input assembly can include a keyboard or a control panel. The body 1 can be a housing support for the input assembly. The first heating element 2, the second heating element 3, and the heat dissipation member 4 can be arranged inside the housing.

The body 1 can include a second surface opposite the first surface. An air inlet member can be provided on the second surface and can be configured to allow the air to enter for the heat dissipation member 4. The air inlet member can be arranged between the first airflow guidance area 71 and the second airflow guidance area 72. Air can enter for the heat dissipation member 4 without affecting the heat dissipation of the first airflow guidance area 71 and the second airflow guidance area 72.

The electronic device can also include a carrier. The carrier can include a first

temperature sensor configured to detect the temperature of the first heating element 2. The first temperature sensor can be communicatively connected to the heat dissipation member 4. The rotation speed of the heat dissipation member 4 can be controlled according to the detected temperature of the first temperature sensor. The carrier can include a second temperature sensor configured to detect the temperature of the second heating element 3. The second temperature sensor can be communicatively connected to the heat dissipation member 4. The rotation speed of the heat dissipation member 4 can be controlled according to the detected temperature of the second temperature sensor.

The carrier can be the motherboard.

Two carriers can be provided to have a one-to-one correspondence with the two heating elements (the first heating element 2 and the second heating element 3). That is, the carrier can include a first carrier and a second carrier that are independent of each other. The first heating element 2 and the first temperature sensor can be arranged on the first carrier. The second heating element 3 and the second temperature sensor can be arranged on the second carrier. Since the first carrier and the second carrier are independent of each other, the first temperature sensor and the second temperature sensor can be independent of each other. The heat dissipation member 4 can be communicatively connected to the first temperature sensor and the second temperature sensor, or the first heat dissipation member 41 and the second heat dissipation member 42 of the heat dissipation member 4 can be communicatively connected to the first temperature sensor and the second temperature sensor, respectively.

In some other embodiments, the carrier can include the first carrier, the second carrier, and a connection member. The connection member can electrically connect the first carrier and the second carrier. The first heating element 2 and the first temperature sensor can be arranged on the first carrier. The second heating element 3 and the second temperature sensor can be arranged on the second carrier. Since the connection member connects the first carrier and the second carrier, the first temperature sensor and the second temperature sensor can be communicatively connected.

With the two carriers (the first carrier and the second carrier), the first heating element 2 and the second heating element 3 can be independent of each other to avoid the mutual impact on the temperatures of the first heating element 2 and the second heating element 3. Thus, the accuracy of the first temperature sensor detecting the temperature of the first heating element 2 and the second temperature sensor detecting the temperature of the second heating element 3 can be effectively improved. Then, the accuracy of the rotation speed adjustment can be further improved for the heat dissipation member 4. Therefore, the heat dissipation performance can be effectively improved.

In some embodiments, the first carrier can include the first heating element 2 and the first temperature sensor. The second carrier can include the second heating element 3 and the second temperature sensor. The first heat dissipation member 41 and the second heat dissipation member 42 of the heat dissipation member 4 can be arranged between the first heating element 2 and the second heating element 3. The first temperature sensor and the second temperature sensor do not interfere with each other. When the temperature of the first heating element 2 is high (CPU with high power consumption), the rotation speed of the heat dissipation member 4 (the first heat dissipation member 41 and/or the second heat dissipation member 42) can be controlled according to the detected temperature of the first temperature sensor of the first carrier. When the temperature of the second heating element 3 is high (GPU with high power consumption), the rotation speed of the heat dissipation member 4 (the first heat dissipation member 41 and/or the second heat dissipation member 42) can be controlled according to the detected temperature of the second temperature sensor of the second carrier. When the temperature difference of the first heating element 2 and the second heating element 3 is smaller than a certain value (e.g., the power consumption difference of CPU and GPU is smaller than a certain vale x W), the rotation speed of the heat dissipation member 4 (the first heat dissipation member 41 and/or the second heat dissipation member 42) can be controlled by the first temperature sensor and the second temperature sensor together.

In some other embodiments, only one carrier can be provided. Thus, the first heating element 2 and the second heating element 3 can be arranged on the carrier symmetrically about the heat dissipation member 4.

In some embodiments, the carrier can include the first temperature sensor of detecting the temperature of the first heating element 2 and the second temperature sensor of detecting the temperature of the second heating element 3. The number of the heat dissipation member 4 can be one. That is, the same heat dissipation member 4 can perform the heat dissipation on the first heating element 2 and the second heating element 3. The heat dissipation member 4 can be communicatively connected to the first temperature sensor and the second temperature sensor. The rotation speed of the heat dissipation member 4 can be controlled according to the detected temperature of the first temperature sensor and the detected temperature of the second temperature sensor. That is, based on the control of the rotation speed of the heat dissipation member 4, the heat dissipation subject of the heat dissipation member 4 can be controlled according to the detected temperature of the first temperature sensor and the detected temperature of the second temperature sensor. For example, when the detected temperature of the first temperature sensor is greater than the detected temperature of the second temperature sensor, the heat dissipation member 4 can perform the heat dissipation on the first heating element 2, or a heat dissipation level performed by the heat dissipation member 4 on the first heating element 2 can be higher than a heat dissipation level performed by the heat dissipation member 4 on the second heating element 3.

In some embodiments, the heat dissipation member 4 can include the first heat dissipation member 41 and the second heat dissipation member 42. The first heat dissipation member 41 can be communicatively connected to the first temperature sensor. The first heat dissipation member 41 can perform the heat dissipation on the first heating element 2. The second heat dissipation member 42 can be communicatively connected to the second temperature sensor. The second heat dissipation member 42 can perform the heat dissipation on the second heating element 3. With the separate controls, the heat dissipation ability of the heat dissipation member can be adjusted accordingly.

In some embodiments, only the first temperature sensor or only the second temperature sensor can be provided.

Embodiments of the present disclosure are described in a progressive manner. Each embodiment focuses on the difference from other embodiments. The same or similar parts among the embodiments of the present disclosure can be referred to each other.

The description of embodiments of the present disclosure can allow those skilled in the art to implement or use the present disclosure. Various modifications to embodiments of the present disclosure are obvious to those skilled in the art. The general principle defined in the present disclosure can be implemented in other embodiments without departing from the spirit or scope of the present disclosure. Thus, the present disclosure is not limited to the described embodiments but should conform to the widest scope consistent with the principles and novel features of the present disclosure.

What is claimed is:

1. An electronic device, comprising:
a body including a first side and a second side arranged opposite to the first side;
a first heating element arranged inside the body close to the first side;
a second heating element arranged inside the body close to the second side; and
a heat dissipation member arranged between the first heating element and the second heating element and configured to dissipate heat for the first heating element and/or the second heating element.

2. The electronic device according to claim 1, wherein:
the first side includes a first vent, and the first heating element is arranged between the first vent and the heat dissipation member; and
the second side includes a second vent, and the second heating element is arranged between the second vent and the heat dissipation member.

3. The electronic device according to claim 1, wherein:
the body includes a third side, and the third side intersects with the first side and the second side; and
the third side includes a third vent, and the heat dissipation member corresponds to the third vent.

4. The electronic device according to claim 3, further comprising a heat conduction member including:
a first heat conduction member connected to the first heating element and/or the second heating element for heat transfer; and
a second heat conduction member corresponding an outlet of the heat dissipation member, airflow flowing out of the outlet of the heat dissipation member being used to dissipate heat for the second heat conduction member.

5. The electronic device according to claim 4, wherein the outlet of the heat dissipation member includes:
a first outlet facing the first side of the body;
a second outlet facing the second side of the body; and/or
a third outlet facing the third side of the body.

6. The electronic device according to claim 1, wherein:
the heat dissipation member includes a first turbine assembly and a second turbine assembly; and
a rotation direction of the first turbine assembly is opposite to a rotation direction of the second turbine assembly.

7. The electronic device according to claim 1, wherein:
an orthogonal projection of the heat dissipation member along a first direction covers an orthogonal projection of the first heating element and the second heating element along the first direction; and
the first direction is an arrangement direction of the first side and the second side.

8. The electronic device according to claim 1, wherein:
the heat dissipation member and the first side form a first airflow guidance area through a flow guidance part, and the first heating element is arranged within the first airflow guidance area; and
the heat dissipation member and the second side form a second airflow guidance area through a flow guidance part, and the second heating element is arranged within the second airflow guidance area.

9. The electronic device according to claim 8, wherein:
the body includes a vent;
a vent arranged at the first airflow guidance area and a vent arranged at the second airflow guidance area each includes a control assembly;
the control assembly is configured to control the vent to be in a first status or a second status; and
an airflow amount of the vent in the first status is different from an airflow amount of the vent in the second status.

10. The electronic device according to claim 1, further comprising a carrier including:
a first temperature sensor configured to detect a temperature of the first heating element and communicatively connected to the heat dissipation member, a rotation speed of the heat dissipation member being controlled according to a detected temperature of the first temperature sensor; and
a second temperature sensor configured to detect a temperature of the second heating element and communicatively connected to the heat dissipation member, a rotation speed of the heat dissipation member being controlled according to a detected temperature of the second temperature sensor.
